(19) United States
(12) Patent Application Publication
(10) Pub. No.: US 2025/0069974 A1
(43) Pub. Date: Feb. 27, 2025

(54) WAFER LEVEL PACKAGING COMPONENT HAVING SIDE WETTABLE STRUCTURE

(71) Applicant: PANJIT INTERNATIONAL INC., Kaohsiung City (TW)

(72) Inventors: CHUNG-HSIUNG HO, Kaohsiung City (TW); JENG-SIAN WU, Taoyuan City (TW)

(21) Appl. No.: 18/470,730

(22) Filed: Sep. 20, 2023

(30) Foreign Application Priority Data
Aug. 24, 2023 (TW) 112131948

(51) Int. Cl. H01L 23/31; H01L 21/56; H01L 23/00; H01L 23/48

(52) U.S. Cl. CPC H01L 23/3114; H01L 21/561; H01L 21/565; H01L 23/481; H01L 24/08; H01L 24/18; H01L 24/97; H01L 2224/08245; H01L 2224/211; H01L 2224/214; H01L 2224/97; H01L 2924/182

(57) ABSTRACT

A wafer level packaging component having a side wettable structure includes a substrate, a function area, a first protective layer, and a redistribution layer (RDL). Half cut grooves are respectively formed on two opposite sides of the substrate. The function area is covered in the substrate, and has conductive pads exposed from a top surface of the substrate. The first protective layer is mounted on the top surface of the substrate, and has openings to expose the conductive pads. The RDL is mounted on the first protective layer, and has redistribution circuits to connect the conductive pads and to extend to the half cut grooves. Since dies are not needed to be cut before packaging the dies, there is no need to process the die bonding process, the molding process, and the grinding process. Processes of manufacturing can be improved, and cost of manufacturing can be decreased.

### BACKGROUND OF THE INVENTION

### 1. Field of the Invention

The present invention relates to packaging technology of a wafer level semiconductor component, especially a wafer level packaging component having a side wettable structure.

### 2. Description of the Related Art

A conventional method for packaging a semiconductor element is dicing a wafer into multiple dies, and the multiple dies are each packaged to be a respective packaged component.

With reference to FIGS. 5 and 6, FIGS. 5 and 6 show a schematic view and a sectional view of one kind of packaging component 50. As shown in FIG. 5, two conductive pads 51 are mounted on one surface of the packaging component 50. As shown in FIG. 6, normally, the packaging component 50 includes a die 52 and a redistribution layer (RDL) 53. The die 52 is mounted in a first substrate 501, such as an epoxy molding compound (EMC). Two connecting pins 522 on a top surface 521 of the die 52 are connected to the conductive pads 51 on the surface of the packaging component 50 through a redistribution circuit 531 in the RDL 53. Two opposite sides of the first substrate 501 are respectively mount on a second substrate 502 and a third substrate 503. The RDL 53 is mounted in the second substrate 502. The third substrate 503 covers a bottom surface 523 of the die 52.

Since the conventional packaging method for packaging the packaging component 50 needs dicing the wafer (not shown) into the multiple dies 52, when the die 52 is packaged, the die needs to be processed by the die bonding process, the molding process, the grinding process, etc., to complete packaging the die 52.

The packaging component 50 packaged by the conventional packaging method has the following disadvantages:
1. Since the die bonding process, the molding process, and the grinding process are needed, cost for manufacturing the packaging component 50 is increased.
2. The use of the EMC as a material of the substrate may cause heat dissipation problems.

### SUMMARY OF THE INVENTION

According to a preferred embodiment of the present invention, the present invention provides a wafer level packaging component having a side wettable structure, and the wafer level packaging component includes a substrate, a function area, a first protective layer, and a redistribution layer (RDL).

The substrate has a top surface and two relative first side surfaces. Two opposite sides of the top surface respectively connect the two first side surfaces, and half cut grooves are respectively formed in connection areas between the two first side surfaces and the top surface. The two first side surfaces are opposite to each other.

The function area is covered by the substrate, and multiple conductive pads are formed on an upper surface of the function area. The multiple conductive pads of the function area are respectively exposed from the top surface of the substrate.

The first protective layer is mounted on the top surface of the substrate and has multiple openings. The multiple conductive pads of the function area are respectively exposed from the top surface of the substrate via the openings of the first protective layer.

The RDL is mounted on an upper surface of the first protective layer, and has multiple redistribution circuits. The multiple redistribution circuits each respectively have a connecting terminal and a welding terminal. The connecting terminals of the multiple redistribution circuits are respectively electrically connected to the multiple conductive pads of the function area. The welding terminals of the multiple redistribution circuits are respectively electrically extended to the half cut grooves of the substrate.

According to another preferred embodiment of the present invention, the present invention further provides a manufacturing method of the wafer level packaging component having the side wettable structure, and the manufacturing method includes steps of:
preparing a wafer; wherein the wafer has a substrate, multiple function areas, and multiple cutting lines; wherein the multiple cutting lines are respectively formed between the multiple function areas; wherein multiple conductive pads are formed on an upper surface of each of the multiple function areas;
downward half cutting an upper surface of the wafer on the cutting lines of the wafer to form multiple half cut grooves;
forming a first protective layer on the upper surface of the wafer; wherein the first protective layer has multiple openings, and the conductive pads of the function areas are respectively exposed out from the openings of the first protectively layer;
forming an RDL on an upper surface of the first protectively layer; wherein the RDL has multiple redistribution circuits, and the redistribution circuits each respectively have a connecting terminal and a welding terminal; wherein the connecting terminals of the redistribution circuits are respectively electrically connected to the conductive pads of the function areas, and the welding terminals of the redistribution circuits are respectively extended to the half cut grooves.

Compared with the prior art, the present invention does not need dicing the wafer into dies before packaging the dies. The present invention can directly form the side wettable structure in the half cut grooves of the wafer. Therefore, the present invention does not need the die bonding process, the molding process, and the grinding process. Further, the substrate is made of a substrate material of the wafer, not the EMC. Hence, the present invention can improve a process of manufacturing, can improve heat dissipation problems caused by the EMC, and can decrease cost of manufacturing.

### BRIEF DESCRIPTION OF THE DRAWINGS

FIG. 1 is a schematic view of a wafer level packaging component having a side wettable structure of the present invention.

FIG. 2 is a sectional view of the wafer level packaging component having the side wettable structure of the present invention.

FIGS. 3A to 3H are flowcharts of a first embodiment of a manufacturing method of the wafer level packaging component having the side wettable structure of the present invention.

FIGS. 4A to 4F are flowcharts of a second embodiment of the manufacturing method of the wafer level packaging component having the side wettable structure of the present invention.

FIG. 5 is a schematic view of a conventional packaged component.

FIG. 6 is a sectional view of the conventional packaged component.

### DETAILED DESCRIPTION OF THE INVENTION

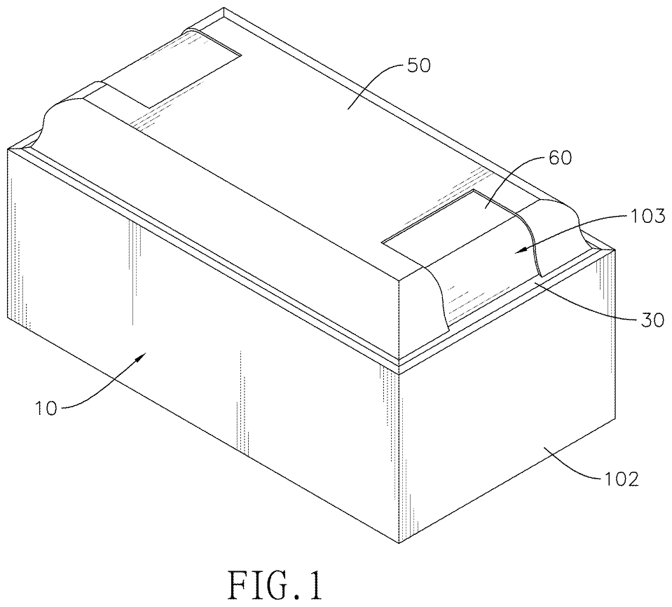

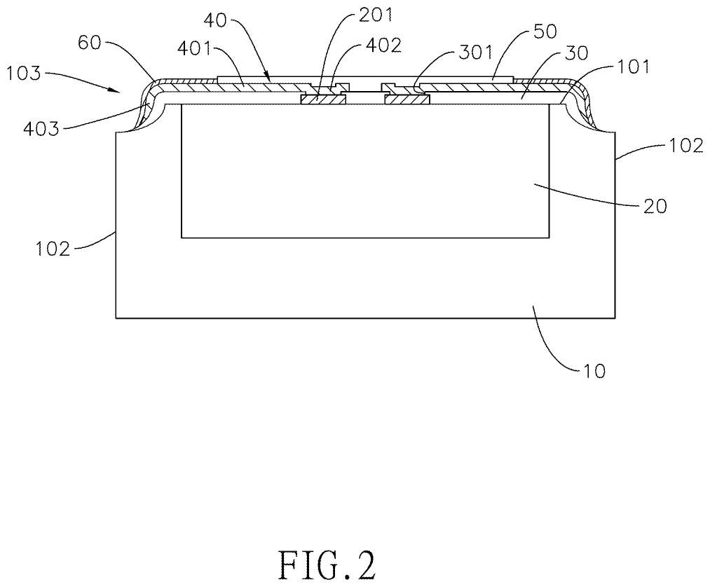

The present invention is a wafer level packaging component 1 having a side wettable structure. With reference to FIGS. 1 and 2, FIGS. 1 and 2 show a schematic view and a sectional view of the wafer level packaging component 1 having the side wettable structure. The wafer level packaging component 1 includes a substrate 10, a function area 20, a first protective layer 30, a redistribution layer (RDL) 40, a second protective layer 50, and multiple edge welding pads 60.

The substrate 10 includes a top surface 101 and two relative first side surfaces 102. Two sides of the top surface 101 respectively connect the two first side surfaces 102, and half cut grooves 103 are respectively formed in connection areas between the two side surfaces 102 and the top surface 101. Preferably, the substrate 10 is made of a silicon dielectric material or a silicon, and the two first side surfaces 102 are opposite to each other.

The function area 20 is covered by the substrate 10, and multiple conductive pads 201 are formed on an upper surface of the function area 20. The multiple conductive pads 201 of the function area 20 are respectively exposed from the top surface 101 of the substrate 10.

The first protective layer 30 is mounted on the top surface 101 of the substrate 10, and has multiple openings 301. The multiple conductive pads 201 of the function area 20 are respectively exposed from the top surface 101 of the substrate 10 via the openings 301 of the first protective layer 30. Preferably, the first protective layer 30 is made of a polyimide (PI) material.

The RDL 40 is mounted on an upper surface of the first protective layer 30, and has multiple redistribution circuits 401. The multiple redistribution circuits 401 each respectively have a connecting terminal 402 and a welding terminal 403. The connecting terminals 402 of the multiple redistribution circuits 401 are respectively electrically connected to the multiple conductive pads 201 of the function area 20. The welding terminals 403 of the multiple redistribution circuits 401 are respectively electrically extended to the half cut grooves 103 of the substrate 10.

The second protective layer 50 is mounted on an upper surface of the RDL 40, and covers the connecting terminals 402 of the redistribution circuits 401. Preferably, the second protective layer 50 is made of a polyimide (PI) material

The edge welding pads 60 are respectively electrically connected to the welding terminals 403 of the redistribution circuits 401. One side surface of each of the edge welding pads 60 is an inner arc surface. A spacing is formed between the substrate 10 and each of the edge welding pads 60. Namely, the edge welding pads 60 do not directly contact the substrate 10.

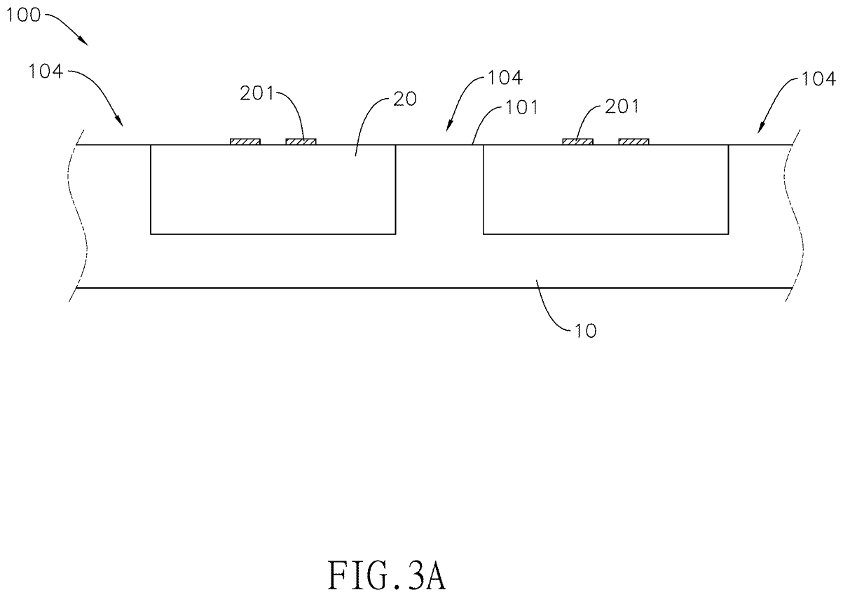

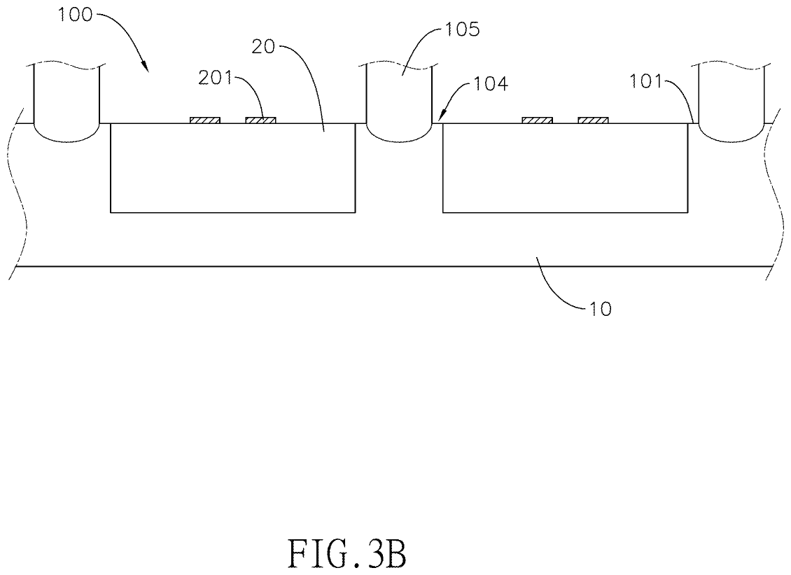

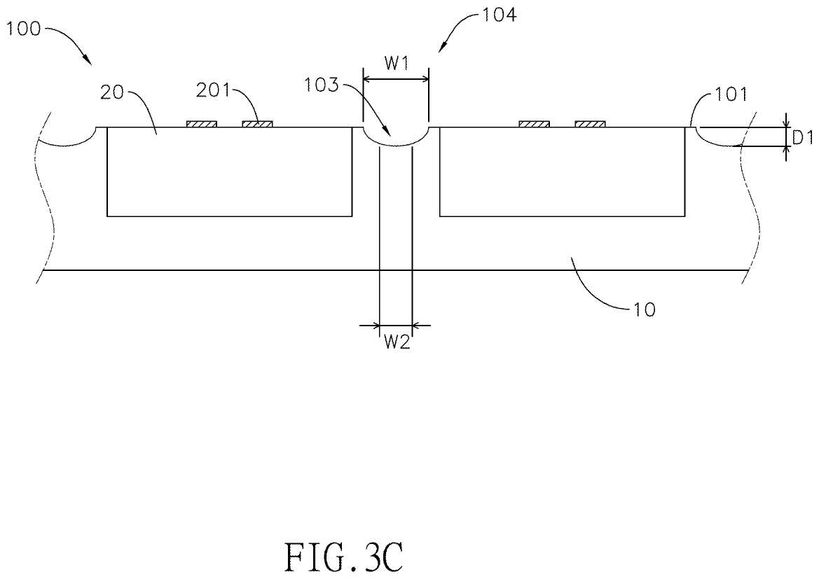

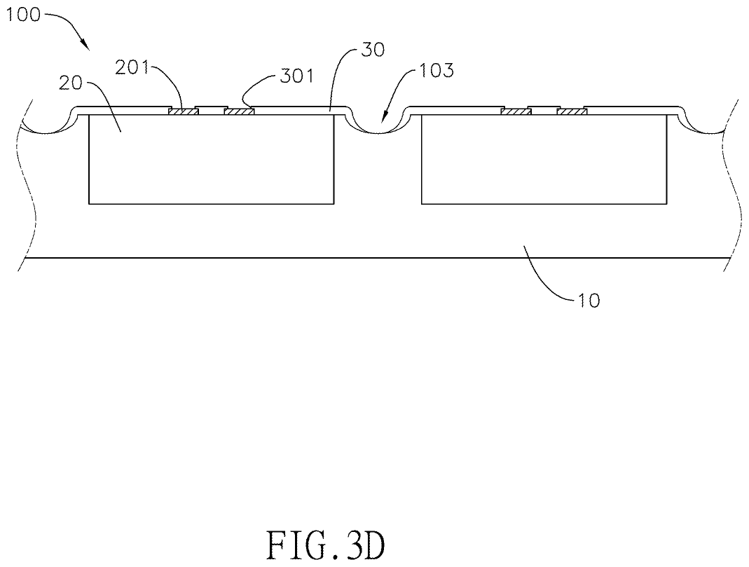

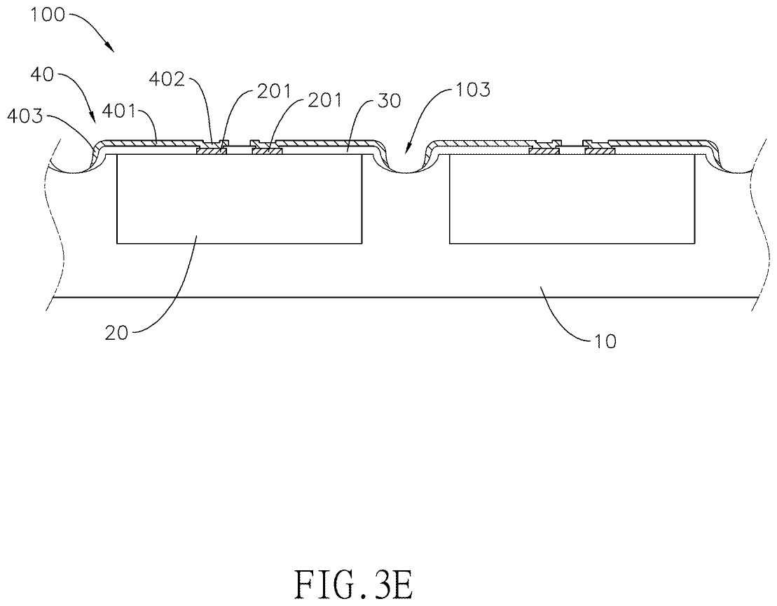

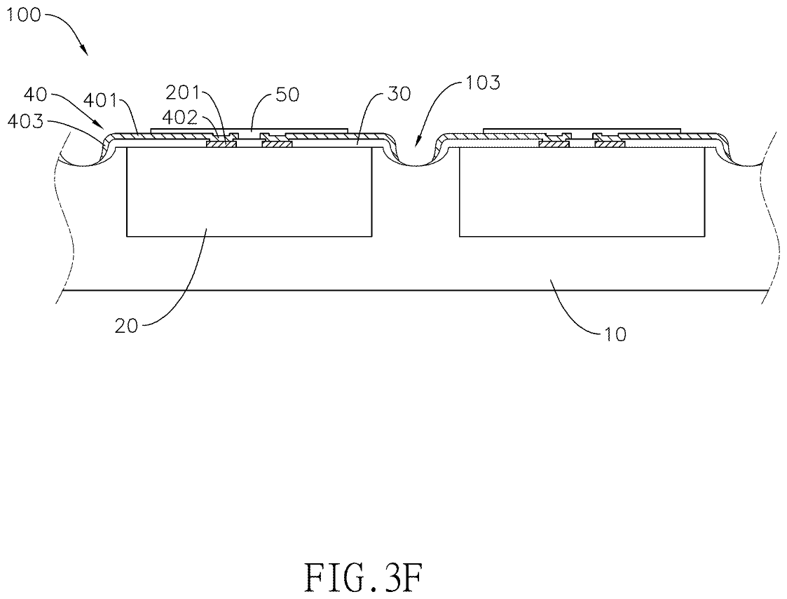

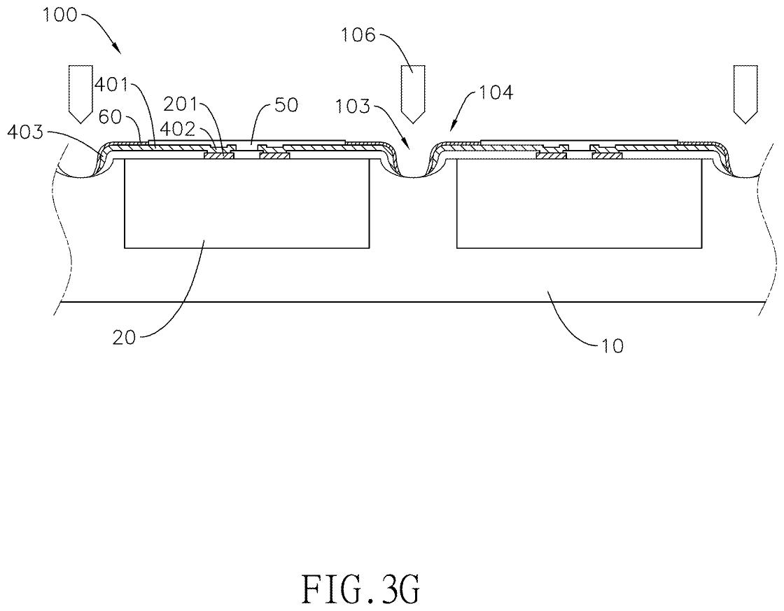

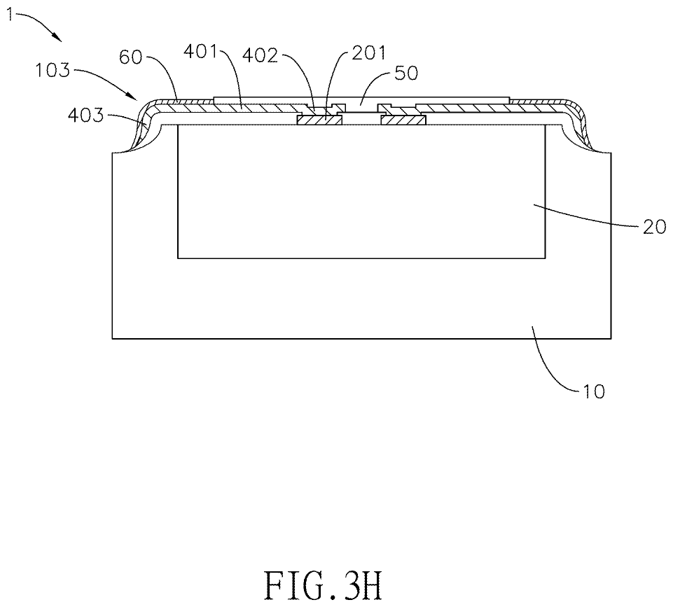

Moreover, according to a first embodiment of the present invention, FIGS. 3A to 3H show flowcharts of a manufacturing method of the wafer level packaging component having the side wettable structure, and the manufacturing method includes steps as follows.

With reference to FIG. 3A, firstly, prepare a wafer 100. The wafer 100 has a substrate 10, multiple function areas 20, and multiple cutting lines 104. The multiple cutting lines 104 are respectively formed between the multiple function areas 20. Multiple conductive pads 201 are formed on an upper surface of each of the multiple function areas 20.

With reference to FIG. 3B, downward half cut an upper surface of the wafer 100 on the cutting lines 104 of the wafer 100 by a half cut blade 105.

With reference to FIG. 3C, after downward half cutting the upper surface of the wafer 100 on the cutting lines 104 of the wafer 100, form multiple half cut grooves 103 in the cutting lines 104 of the wafer 100.

With reference to FIG. 3D, accordingly, form a first protective layer 30 on the upper surface of the wafer 100. The first protective layer 30 has multiple openings 301, and the conductive pads 201 of the function areas 20 are respectively exposed out from the openings 301 of the first protectively layer 30. In the embodiment, the openings 301 are formed by etching, lasering, or processing photolithography to the first protective layer 30. Further, for example, a groove opening width W1 of each half cut groove 103 may be 50 to 200 μm, a groove bottom width W2 of each half cut groove 103 may be smaller than the groove opening width W1, and a groove depth D1 is not greater than half of a thickness of the wafer 100.

With reference to FIG. 3E, further, form an RDL 40 on an upper surface of the first protectively layer 30. The RDL 40 has multiple redistribution circuits 401, and the redistribution circuits 401 each respectively have a connecting terminal 402 and a welding terminal 403. The connecting terminals 402 of the redistribution circuits 401 are respectively electrically connected to the conductive pads 201 of the function areas 20, and the welding terminals 403 of the redistribution circuits 401 are respectively extended to the half cut grooves 103.

With reference to FIG. 3F, respectively form a second protectively layer 50 on an upper surface of the RDL 40 in positions corresponding to the function areas 20. The second protectively layers 50 respectively cover the connecting terminals 402 of the redistribution circuits 401.

With reference to FIG. 3G, respectively form an edge welding pad 60 on an upper surface of each of the welding terminals 403 of the redistribution circuits 401. Preferably, one side surface of each of the edge welding pads 60 is an inner arc surface.

With reference to FIGS. 3G and 3H, moreover, downward fully cut the substrate 10 of the wafer 100 from the upper surface of the wafer 100 on the cutting lines 104 of the wafer 100 by a full cut blade 106. Accordingly, multiple independent wafer level packaging components 1 are formed.

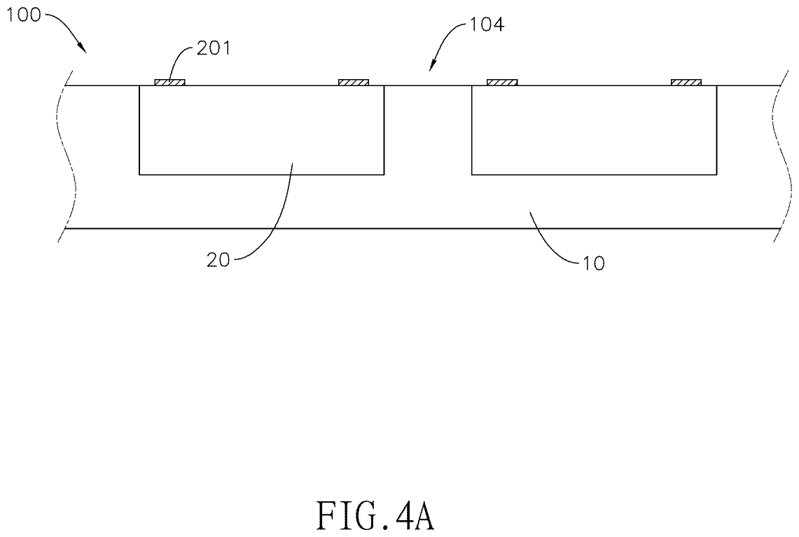

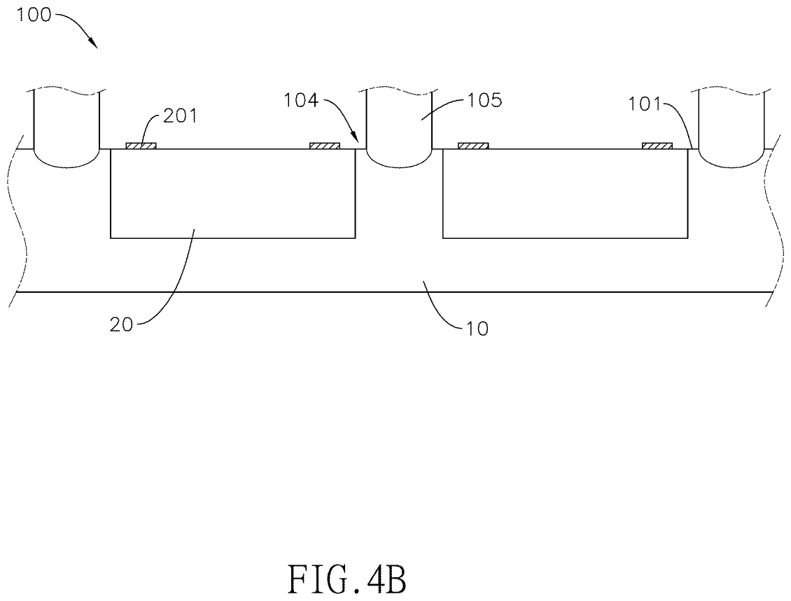

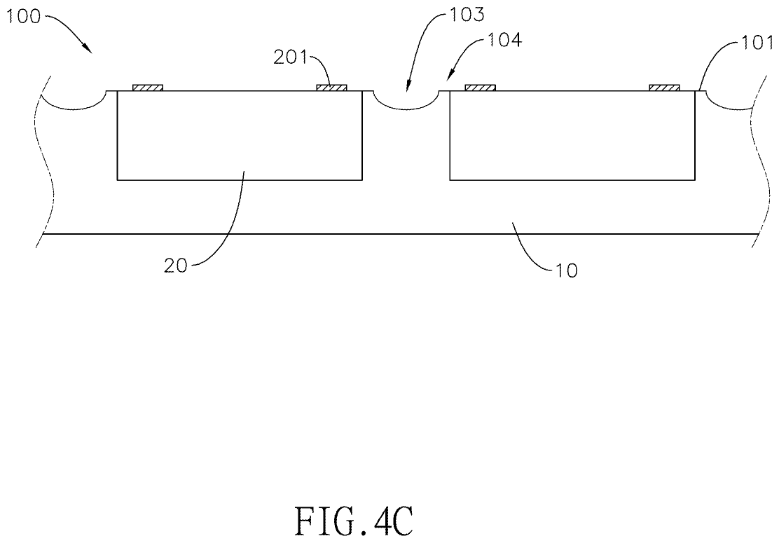

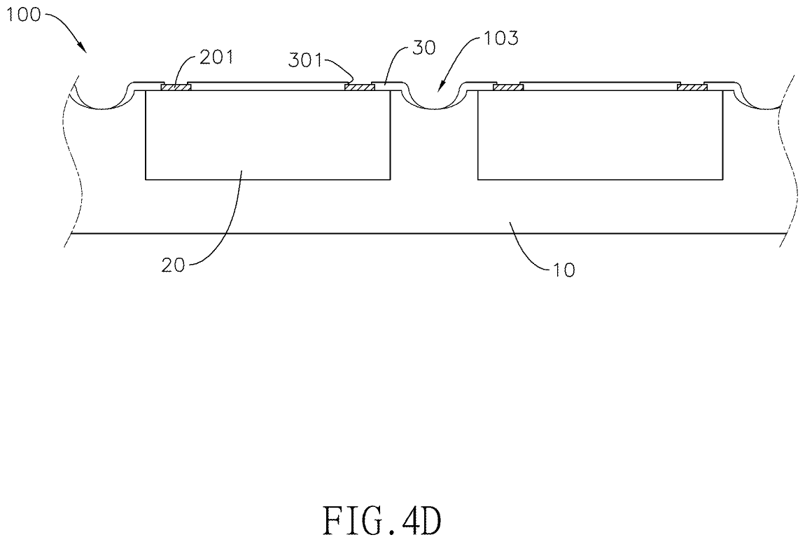

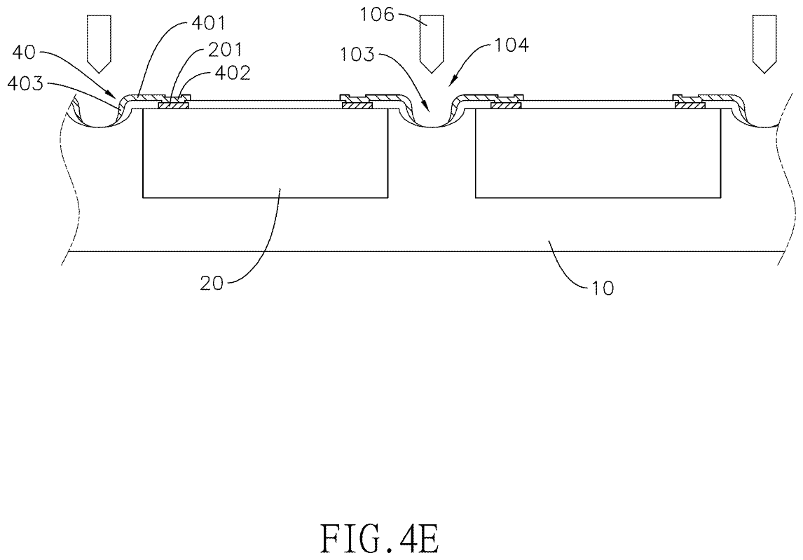

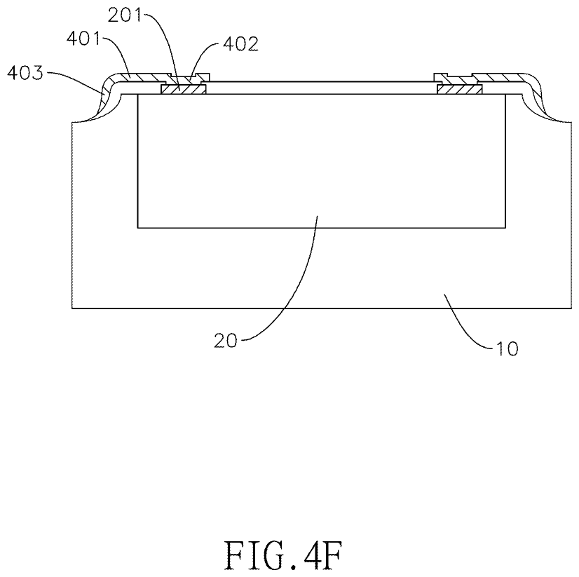

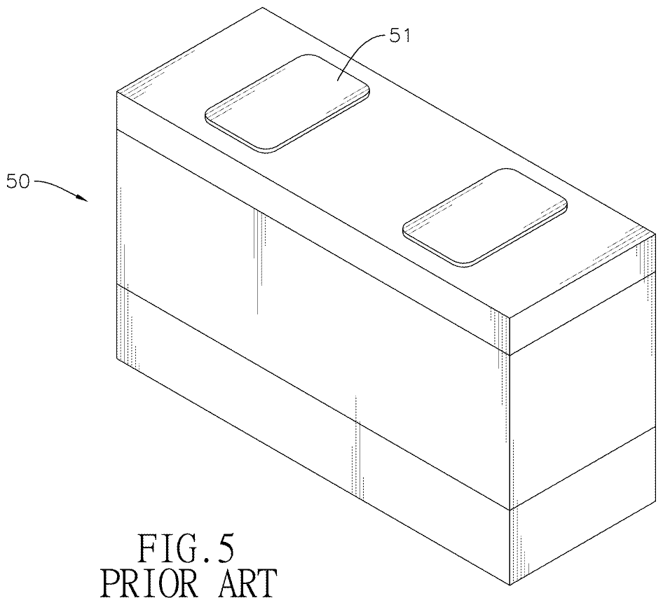

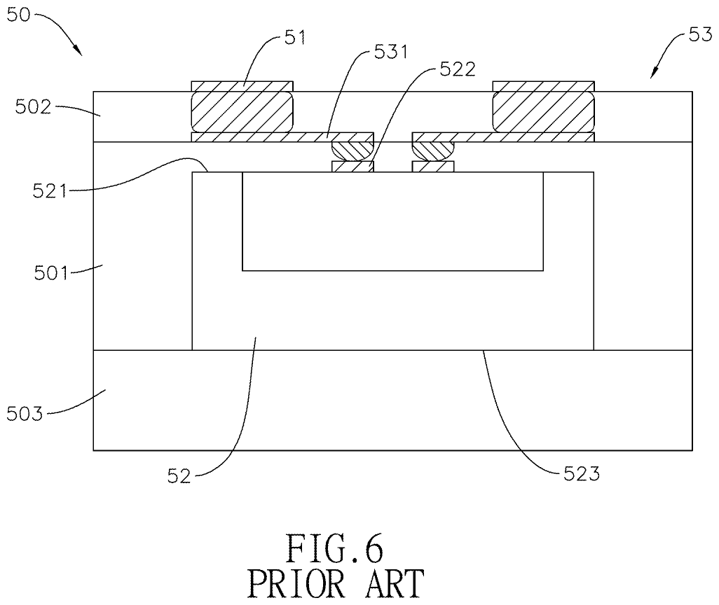

Furthermore, according to a second embodiment of the present invention, FIGS. 4A to 4F show flowcharts of the manufacturing method, and the manufacturing method includes steps as follows.

With reference to FIG. 4A, firstly, prepare a wafer 100. The wafer 100 has a substrate 10, multiple function areas 20, and multiple cutting lines 104. The multiple cutting lines 104 are respectively formed between the multiple function areas 20. Multiple conductive pads 201 are formed on an upper surface of each of the multiple function areas 20.

With reference to FIG. 4B, downward half cut an upper surface of the wafer 100 on the cutting lines 104 of the wafer 100 by a half cut blade 105.

With reference to FIG. 4C, after downward half cutting the upper surface of the wafer 100 on the cutting lines 104 of the wafer 100, form multiple half cut grooves 103 in the cutting lines 104 of the wafer 100. With reference to FIG. 4D, accordingly, form a first protective layer 30 on the upper surface of the wafer 100. The first protective layer 30 has multiple openings 301, and the conductive pads 201 of the function areas 20 are respectively exposed out from the openings 301 of the first protectively layer 30.

With reference to FIG. 4E, further, form an RDL 40 on an upper surface of the first protectively layer 30. The RDL 40 has multiple redistribution circuits 401, and the redistribution circuits 401 each respectively have a connecting terminal 402 and a welding terminal 403. The connecting terminals 402 of the redistribution circuits 401 are respectively electrically connected to the conductive pads 201 of the function areas 20, and the welding terminals 403 of the redistribution circuits 401 are respectively extended to the half cut grooves 103.

With reference to FIGS. 4E and 4F, moreover, downward fully cut the substrate 10 of the wafer 100 from the upper surface of the wafer 100 on the cutting lines 104 of the wafer 100 by a full cut blade 106. Accordingly, multiple independent wafer level packaging components 1 are formed.

In the second embodiment, since the conductive pads 201 of the function areas 20 are far away from each other, the second protective layer 50 and the edge welding pads 60 are not needed.

In conclusion, compared with a conventional packaged component, the wafer level packaging component 1 of the present invention not only has the advantage of a side wettable structure, but also has advantages as follows:
1. The present invention does not need dicing the wafer 100 into dies before packaging the dies into packaging material. The present invention can directly form the side wettable structure in the half cut grooves 103 of the wafer 100, and then the wafer 100 can be fully cut into multiple independent wafer level packaging components 1 having the side wettable structure. Therefore, the present invention does not need the die bonding process, the molding process, and the grinding process, decreasing cost of manufacturing.
2. The substrate 10 is made of a substrate material of the wafer 100, such as a silicon dielectric material or a silicon, not EMC. Therefore, heat dissipation problems caused by the EMC can be mitigated.

What is claimed is:

1. A wafer level packaging component having a side wettable structure, comprising:
a substrate, having a top surface and two relative first side surfaces; wherein two opposite sides of the top surface respectively connect the two first side surfaces, and half cut grooves are respectively formed in connection areas between the two first side surfaces and the top surface;
a function area, covered by the substrate; wherein multiple conductive pads are formed on an upper surface of the function area, and the multiple conductive pads of the function area are respectively exposed from the top surface of the substrate;
a first protective layer, mounted on the top surface of the substrate, and having multiple openings; wherein the multiple conductive pads of the function area are respectively exposed from the top surface of the substrate via the openings of the first protective layer;
a redistribution layer (RDL), mounted on an upper surface of the first protective layer, and having multiple redistribution circuits; wherein the multiple redistribution circuits each respectively have a connecting terminal and a welding terminal; wherein the connecting terminals of the multiple redistribution circuits are respectively electrically connected to the multiple conductive pads of the function area, and the welding terminals of the multiple redistribution circuits are respectively electrically extended to the half cut grooves of the substrate.

2. The wafer level packaging component having the side wettable structure as claimed in claim 1, further comprising:
a second protective layer, mounted on an upper surface of the RDL, and covering the connecting terminals of the redistribution circuits.

3. The wafer level packaging component having the side wettable structure as claimed in claim 1, further comprising:
multiple edge welding pads, formed on an upper surface of each of the welding terminals of the redistribution circuits.

4. The wafer level packaging component having the side wettable structure as claimed in claim 3, wherein the multiple edge welding pads are respectively electrically connected to the welding terminals of the redistribution circuits; wherein one side surface of each of the edge welding pads is an inner arc surface.

5. The wafer level packaging component having the side wettable structure as claimed in claim 3, wherein a spacing is formed between the substrate and each of the edge welding pads.

6. The wafer level packaging component having the side wettable structure as claimed in claim 1, wherein the substrate is made of a silicon dielectric material.

7. The wafer level packaging component having the side wettable structure as claimed in claim 1, wherein the first protective layer is made of a Polyimide (PI) material.

8. The wafer level packaging component having the side wettable structure as claimed in claim 1, wherein the second protective layer is made of a Polyimide (PI) material.

9. The wafer level packaging component having the side wettable structure as claimed in claim 1, wherein the half cut groove has a groove bottom width smaller than a groove opening width, the groove opening width of the half cut groove ranges from 50 to 200 μm.

10. The wafer level packaging component having the side wettable structure as claimed in claim 1, wherein each of the half cut groove is formed by downward cutting a cutting line between the plurality of the function area.
